(19) United States
(12) Patent Application Publication
(10) Pub. No.: US 2013/0153006 A1
(43) Pub. Date: Jun. 20, 2013

(54) SELF-ERECTING PORTABLE PHOTOVOLTAIC PANEL SYSTEM AND METHOD

(71) Applicants: Donald P. Cox, Oro Valley, AZ (US); Donald R. McMonagle, Tucson, AZ (US)

(72) Inventors: Donald P. Cox, Oro Valley, AZ (US); Donald R. McMonagle, Tucson, AZ (US)

(73) Assignee: Raytheon Company, Waltham, MA (US)

(21) Appl. No.: 13/327,550

(22) Filed: Dec. 15, 2011

(51) Int. Cl. H01L 31/048; H01L 31/18

(52) U.S. Cl. 136/251; 29/890.033

(57) ABSTRACT

A photovoltaic power system includes a flexible panel (105) comprising a plurality of photovoltaic cells (305) configured to convert solar energy into electrical energy. The photovoltaic power system also includes an inflatable support frame (110) coupled to the flexible support panel, where the inflatable support frame is configured to support to the flexible panel when inflated by a gaseous solution. In addition, the photovoltaic power system may include a control canister (115) configured to store the gaseous solution and to provide the gaseous solution to the inflatable support frame.

### TECHNICAL FIELD

This disclosure is directed in general to power supply systems and more specifically to a self-erecting portable photovoltaic panel system and method.

### BACKGROUND OF THE DISCLOSURE

Various power supply systems are known. However, some of these systems include components that unnecessarily increase the size and complexity of power supply configurations. Further, some power supply system configurations have unacceptable transportation and repair requirements.

### SUMMARY OF THE DISCLOSURE

To address one or more deficiencies of the prior art, one embodiment described in this disclosure provides a photovoltaic power system that includes a flexible photovoltaic panel and an inflatable mounting frame. The photovoltaic panel includes a plurality of photovoltaic cells configured to convert solar energy into electrical energy. The inflatable mounting frame is adapted to receive a gaseous solution through an inflation connection point. The inflatable mounting frame is configured to, when inflated by a gaseous solution, provide a rigid or semi-rigid support to the flexible photovoltaic panel. The photovoltaic power system also can include a control canister. The control canister is configured to store the gaseous solution and provide the gaseous solution to the inflatable mounting frame.

Certain embodiments may provide various technical advantages depending on the implementation. For example, a technical advantage of some embodiments may include the ability to provide a compact solar panel system that can fit within a small container for transport and that can self-erect to full size for deployment. Another technical advantage may include the ability to provide a resilient photovoltaic panel configured to deliver a required voltage despite damage to a portion of the panel. Yet another technical advantage may include the ability to provide an electrical network with a portable photovoltaic power supply.

Although specific advantages have been enumerated above, various embodiments may include some, none, or all of the enumerated advantages. Additionally, other technical advantages may become readily apparent to one of ordinary skill in the art after review of the following figures and description.

### BRIEF DESCRIPTION OF THE DRAWINGS

For a more complete understanding of this disclosure and its advantages, reference is now made to the following description taken in conjunction with the accompanying drawings, in which like reference numerals represent like parts:

FIG. 1 illustrates an example photovoltaic panel system according to this disclosure;

FIG. 2 illustrates an example photovoltaic array according to this disclosure;

FIGS. 3A and 3B illustrate an example thin-film photovoltaic panel according to this disclosure;

FIGS. 4A and 4B illustrate an example inflatable support frame according to this disclosure; and

FIGS. 5 through 7 illustrate example electrical networks according to this disclosure.

### DETAILED DESCRIPTION

It should be understood at the outset that, although example embodiments are illustrated below, the present invention may be implemented using any number of techniques, whether currently known or not. The present invention should in no way be limited to the example implementations, drawings, and techniques illustrated below. Additionally, the drawings are not necessarily drawn to scale.

In particular configurations, it may be desirable to have a self-erecting portable photovoltaic (PV) power supply to convert solar energy into electrical energy. For solar-to-electrical conversion, conventional configurations may use so-called “solar panel” generators. Additionally, to obtain portability, some configurations utilize smaller solar panels set on rigid mounting frames that maintain the panels at the most efficient orientation to the sun. In non-solar tracking applications, PV panels employ rigid structural forms constructed of lightweight metals or plastics for the mounting frames. However, transportation of the rigid frame members to a deployment site often requires large or cumbersome containers.

Recognizing that such components may be undesirable for certain configurations, certain embodiments disclosed here provide a compact, alignment stable, self-erecting PV system to convert solar energy into electrical energy. Additionally, certain embodiments teach components that are resilient such that damage or loss of a portion of the PV panels does not substantially degrade electrical output.

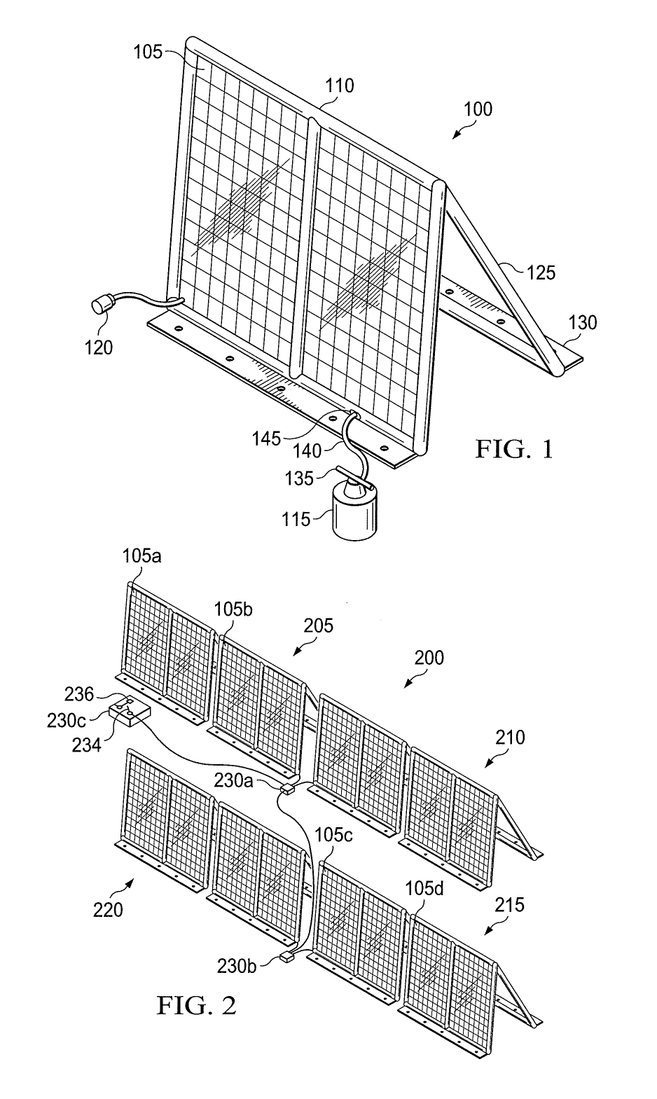

FIG. 1 illustrates an example photovoltaic (PV) panel system 100 according to this disclosure. Although certain details will be provided with reference to the components of the PV panel system 100 of FIG. 1, it should be understood that other embodiments may include more, less, or different components. In this example, the PV panel system 100 includes a thin-film PV panel 105, an inflatable mounting frame 110, a control canister 115 and an electrical connector 120. As described in more detail below, the PV panel system 100 is configured to self-erect so that the PV panel 105 is oriented to convert solar energy into electrical energy.

The thin-film PV panel 105 receives solar energy and converts the solar energy into electrical energy. The thin-film PV panel 105 includes a plurality of PV cells coupled in series, parallel, or a combination of series and parallel. For example, the thin-film PV panel 105 can include a first set of PV cells coupled in series and a second set of PV cells also coupled in series. The first set of PV cells can be coupled in parallel with the second set of PV cells. These two sets of PV cells further can be coupled with a third set of PV cells and so forth. The PV cells can be configured such that, should one or more of the PV cells be damaged or otherwise cease to function, the remaining PV cells continue to function and can deliver the same or similar voltage as when all PV cells are functioning properly. For example, if the thin-film PV panel 105 in normal operation is configured to deliver 12 volts (V) and one or more PV cells in the first set of PV cells are damaged, the remaining sets of PV cells can continue to deliver 12V.

The thin-film PV panel 105 is coupled along a support surface of the inflatable mounting frame 110. The inflatable mounting frame 110 is pliable and compactable (such as by folding or rolling). The inflatable mounting frame 110 can be inflated by the insertion of gas from the control canister 115. Upon receiving gas from the control canister 115, various components in the inflatable mounting frame 110 expand to provide a rigid or semi-rigid support for the thin-film PV panel 105. In addition, as the components in the inflatable mounting frame 110 expand, the inflatable mounting frame 110 erects and opens the thin-film PV panel 105 to a position where the thin-film PV panel 105 can receive solar energy. In certain embodiments, the inflatable mounting frame 110 is coupled to one or more corners or edges of the thin-film PV panel 105. In other embodiments, the inflatable mounting frame 110 is coupled to the thin-film PV panel 105 along an entire under-surface of the thin-film PV panel 105.

In certain embodiments, the inflatable mounting frame 110 includes an adjustable brace 125. The adjustable brace 125 is a movable frame element that adjusts an orientation of the thin-film PV panel 105. In certain embodiments, the adjustable brace 125 is rotatably coupled to one edge of the inflatable mounting frame 110. In some embodiments, the adjustable brace 125 is a rigid support member made of steel, aluminum, plastic, or other suitable material(s). In other embodiments, the adjustable brace 125 also is inflatable. In still other embodiments, the adjustable brace 125 is collapsible into sections, such as by one or more of sliding, folding, curling and so forth. In yet other embodiments, the adjustable brace 125 is detachably coupled to the inflatable mounting frame 110.

In certain embodiments, the inflatable mounting frame 110 includes an anchor member 130. The anchor member 120 provides a securing mechanism to maintain an orientation of the thin-film PV panel 105. The anchor member 130 also can provide a ground anchor for the PV system 100 so that the thin-film PV panel 105 cannot be readily moved, such as by wind or collision with another object. In certain embodiments, the anchor member 130 is a single anchor cloth that couples on one end to the adjustable brace 125 and on a second end to the support surface of inflatable mounting frame 110 or the thin-film PV panel 105. In other embodiments, the anchor member 130 includes at least two independent members, where a first member is coupled to the adjustable brace 125 and a second member is coupled to the support surface of the inflatable mounting frame 110 or the thin-film PV panel 105.

The control canister 115 stores a high-pressure gas. The control canister 115 includes an inflation hose 140 that is adapted to couple to an inflation attachment point 145 (such as an inflation valve) of the inflatable mounting frame 110. In some embodiments, the inflatable mounting frame 110 includes the inflation hose 140 and the control canister 115 includes an inflation attachment point adapted to couple to the inflation hose 140. The control canister 115 can deliver the high-pressure gas to the inflatable mounting frame 110 in response to an actuation of an inflation control valve 135. For example, an operator can rotate the inflation control valve 135 and release the high-pressure gas. In certain embodiments, the degree to which the inflation control valve 135 is turned regulates an amount of the high-pressure gas released into the inflatable mounting frame 110. In other embodiments, the control canister 115 includes a control panel (not shown) that can release the high-pressure gas into the inflatable mounting frame 110 and can monitor the pressure of the gas in the control canister 115, the inflatable mounting frame 110, or both. For instance, the control canister 115 can include processing circuitry and associated sensors that can monitor the pressure in the control canister 115 or the inflatable mounting frame 110. When activated, the processing circuitry causes the compressed gas to flow from the control canister 115 into the inflatable mounting frame 110 until a desired pressure is achieved within the inflatable mounting frame 110. In particular embodiments, the desired pressure is preset in a memory of the processing circuitry. In some embodiments, the pressure is displayed on a display of the control canister 115 to enable an operator to determine when to shut off the gas flow into the inflatable mounting frame 110. In certain embodiments, the control canister 115 includes a mechanical pressure regulator configured to set a given pressure. Once engaged, control canister 115 can remain on the ground with a regulated pressure applied to the inflatable mounting frame 110. In other embodiments, the processing circuitry can continue monitoring the pressure in the inflatable mounting frame 110 and injecting more gas into the inflatable mounting frame 110 as needed. In certain embodiments, responsive to a command from an operator, the processing circuitry can cause the gas within the inflatable mounting frame 110 to be expelled. That is, the canister's controller can cause the inflatable mounting frame 110 to deflate by controlling an actuator coupled to a valve on the inflation attachment point. In some embodiments, the canister controller 115 deflates the inflatable mounting frame 110 responsive to an overload condition, such as an over-pressure condition in the inflatable mounting frame 110 or a temperature change that may result in an overpressure or freezing of one or more valves. The high-pressure gas can be carbon dioxide (CO₂), an inert gas, or any other suitable gas. In certain embodiments, the control canister 115 includes a separate storage container for holding the gas, and the storage container can be replaced or replenished with new gas as required. In some embodiments, the control canister 115 can inject a foam or other solution that is configured to permanently inflate the inflatable mounting frame 110. For example, the control canister 115 can inject a self-curing epoxy foam into the inflatable mounting frame 110 to inflate the inflatable mounting frame 110. Once cured, the epoxy would become ridged and create a permanently inflated frame. If further transportation is needed, the PV panels can be removed from the now ridged frame, and the frame components can be transported or discarded. In some embodiments, the inflatable support frame 110 is adapted to be inflated by a means other than the control canister 115. For example, the inflatable support frame 110 can include the inflation attachment point 145 (or the inflation hose 140) adapted to receive a gaseous solution from one or more of a pump, human breath, engine exhaust, vacuum cleaner discharge, and the like.

The electrical connector 120 is configured to receive a connection from an electrical device or electrical system. For example, the electrical connector 120 can comprise a female plug receptacle. The electrical connector 120 can be coupled to a junction box (not shown) for coupling with additional PV panel systems 100.

In certain embodiments, the PV panel system 100 is configured to fit in a small travel case when not in use or erected. That is, when the inflatable support frame 110 is not inflated, the thin-film PV panel 105 and inflatable support frame 110 can be collapsed, folded, rolled up, or otherwise made to fit within a small container, such as a bag, back-pack, box, or the like. Additionally, the control canister 115 can be dimensioned to fit within the bag, back-pack, box, or the like.

FIG. 2 illustrates an example PV array 200 according to this disclosure. Although certain details will be provided with reference to the components of the PV array 200 of FIG. 2, it should be understood that other embodiments may include more, less, or different components. In this example, the PV array 200 includes a number of PV panel systems, such as PV Panel system 100 shown in FIG. 1), coupled in series, parallel, or a combination of the two. As described in more detail below, the PV array 200 is configured to be portable and quickly erected to be oriented to convert solar energy into electrical energy.

The PV panel systems 100 can be coupled in a variety of configurations in the array 200 to achieve a desired output, such as a desired voltage, current, or power. In addition, the PV array 200 can include a number of PV panel systems 100 coupled in a series of PV sections. In this example, a first PV panel section 205 includes a number of PV panel systems 100 coupled in series. The voltage output from the first PV panel system 105a is added to the voltage output from the second PV panel system 105b. For example, if the first PV panel system 105a delivers 12V and the second panel system 105b delivers 12V, the output of the first PV panel section 205 is 24V. Additionally, the first PV panel section 205 can be coupled in series with a second PV panel section 210, which also includes a number of PV panel systems 100 coupled in series. The first and second PV panel sections may then be coupled in parallel with a series combination of a third PV panel section 215 and a fourth PV panel section 220. However, the third and forth PV panel sections 215-220 could each include PV panel systems 100 coupled in parallel. For example, if the third PV panel system 105c delivers 24V and the fourth panel system 105d delivers 24V, the output of the third PV panel section 215 is 24V. It should be understood that the aforementioned connections are for illustration only. The connections within each panel section 205-220 could be series, parallel, or a combination thereof. The connections between each panel section 205-220 could be series, parallel, or a combination thereof. It should be understood that the voltages described are for illustration and the PV panel system 100 can be configured to operate within a range of voltages. In one example, the range of voltages is between zero (0) and four-hundred-eighty (480) volts. In one example, the PV panel system 100 includes eighty-eight volt cells. The PV panel system 100 also can include an adapter to change volts a Maximum Power Point converter or a pulse width converter.

Each PV panel system 100 and each PV panel section 205-220 can be coupled together by one or more electrical junction boxes 230a-230c. For example, a first junction box 230a can couple the first PV panel system 105a in series with the second PV panel system 105b. In addition, a second junction box 230b can couple the third PV panel section 215 in series with the fourth PV panel section 220. Further, a third junction box 230c can couple the first and second PV panel sections 205-210 in parallel with the third and fourth PV panel sections 215-220.

In certain embodiments, the inflatable support frame 110 for one PV panel system 100 is configured to couple to another inflatable support frame 110 for another PV panel system 100. For instance, the inflatable support frame 110 for the first PV panel system 105a can couple to the inflatable support frame 110 for the second PV panel system 105b. In particular embodiments, the inflatable support frames 110 can couple to each other at preset orientations. In other particular embodiments, the inflatable support frames 110 can couple to each other at adjustable orientations. The inflatable support frames 110 can include a valve configured to prevent a reverse or sudden flow of gas from one frame 110 to another to prevent or inhibit one frame 110 from deflating a connected frame 110. For example, the inflatable support frame 110 can include a valve that includes settings to allow a flow of gas during planned inflation and deflation and another setting that inhibits a flow of gas, such as when an adjacent inflatable mounting frame 110 is punctured or otherwise damaged. Accordingly, the PV panel systems 100 within the PV panel array 200 can be adjusted to be at different orientations with respect to each other.

Setting each PV panel system 100 or PV panel section 205-220 at different orientations enables different ones of the PV panel systems 100 to be at the most efficient orientation to receive solar energy as the sun traverses through the sky. For example, during a first part of the day, the first PV panel section 205 may be oriented to receive the most sunlight, while the second PV panel section 210 may be oriented to receive the most sunlight later in the day. In certain embodiments, each electrical junction box 230a-230c includes a switch 234 and controller 236 configured to detect which ones of the PV panel systems are generating electrical energy. The controller can operate the switch 234 such that the PV panel system 100 generating electrical energy is connected to deliver that electrical energy, while a PV panel system 100 not generating electrical energy is electrically disconnected from the array.

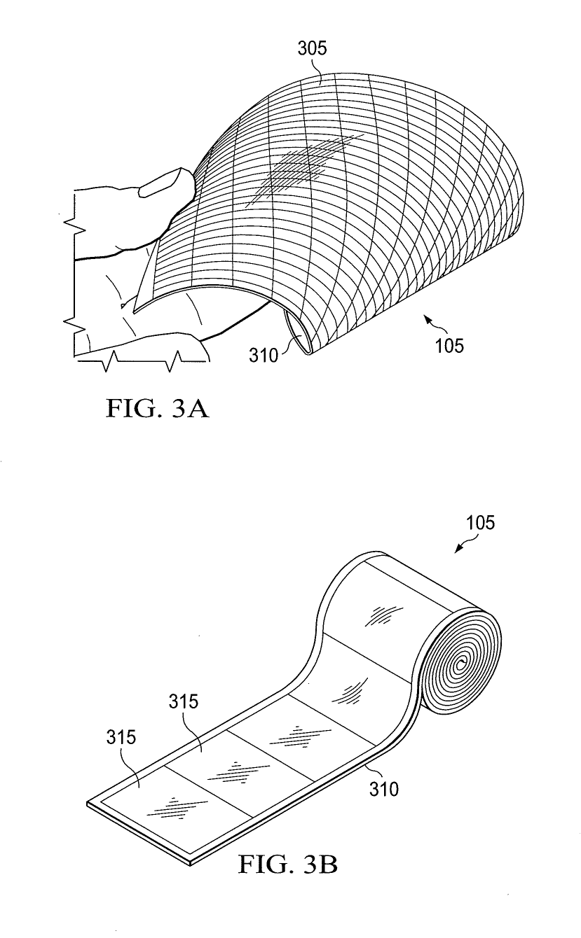

FIGS. 3A and 3B illustrate an example thin-film photovoltaic panel 105 according to this disclosure. Although certain details will be provided with reference to the components of the thin-film PV panel 105 of FIGS. 3A and 3B, it should be understood that other embodiments may include more, less, or different components. In this example, the thin-film PV panel 105 includes a plurality of PV cells 305 and a flexible support panel 310. As described in more detail below, the thin-film PV panel 105 is configured to be compactable and convert solar energy into electrical energy.

The flexible support panel 310 can be pliable. For example, the flexible support panel 310 can be a MYLAR or other non-conductive plasticized material. The active PV cells 305 can be imprinted onto the flexible support panel 310. For example, an amorphic process may be used to deposit a homogenous coating of PV cells 305 onto the plasticized material. In another example, a crystallized PV cell is applied to the plasticized material such that, although the PV cells are rigid, the combination of cells and plasticized material remains substantially flexible. The PV cells 305 can be imprinted such that the PV cells 305 are connected in series, parallel, or a combination thereof. In addition, the PV cells 305 can be arranged into a series of PV cell sections 315 as shown in FIG. 3B, where one or more sections 315 may be coupled together to form the thin-film PV panel 105. Accordingly, the thin-film PV panel 105 is formed by the imprinting of the PV cells 305 onto the flexible support panel 310. In certain embodiments, the thin-film PV panel 105 can be rolled, folded, or a combination of the two. For example, the thin-film PV panel 105 could be folded along seams, such as into halves, thirds, quarters and so forth.

In certain embodiments, the thin-film panel 105 includes resiliency and low maintenance requirements. The thin-film panel 105 can maintain power output despite damage to the thin-film panel 105. For example, if a portion of the thin-film panel 105 is punctured from a tree limb, rock, sharp object, bullet or other object, the undamaged portion of the thin-film panel 105 can continue to convert solar energy into electrical energy. Accordingly, rips, tears or perforations of the thin-film panel 105 may not seriously degrade electrical output. In certain embodiments, damaged portions of the thin-film panel 105 can be replaced by new or otherwise undamaged sections of another thin-film panel 105. Since the thin-film panel 105 is formed on a pliable material, the thin-film panel 105 is resistant to breaking or cracking. Therefore, minimal maintenance such as washing may be required. For example, cells in the panels can include re-configurable connectors such that the PV cell circuits can be re-wired to bypass a damaged cell or cells until permanent repairs can be made.

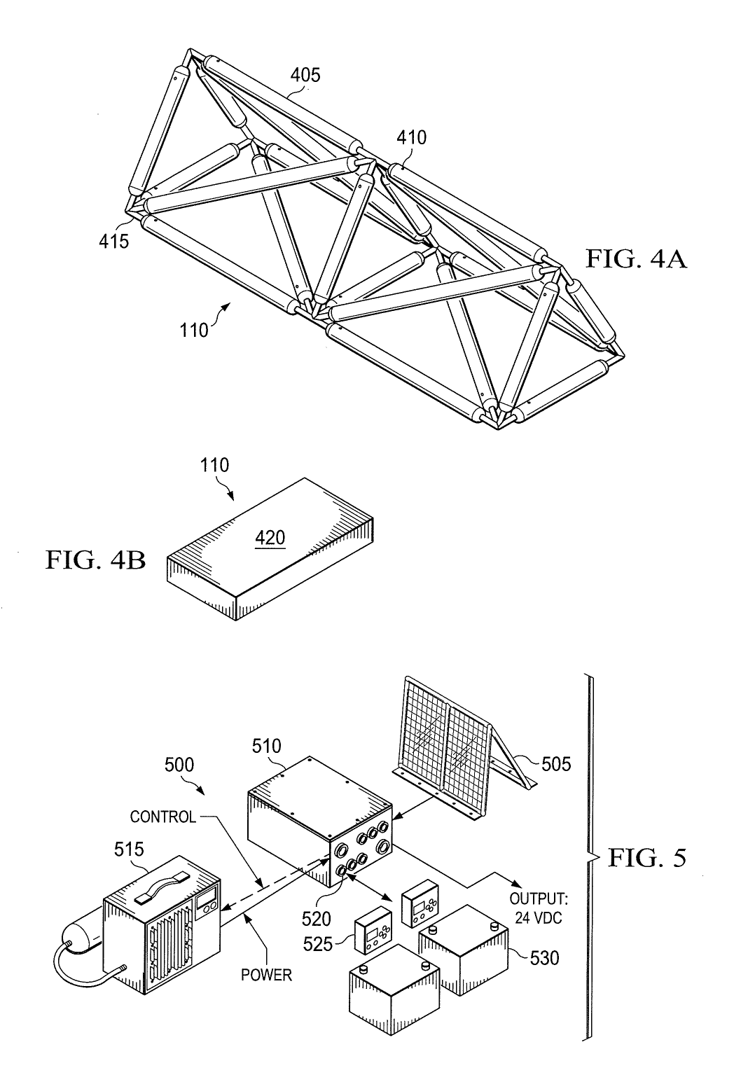

FIGS. 4A and 4B illustrate an example inflatable support frame 110 according to this disclosure. Although certain details will be provided with reference to the components of the inflatable support frame 110 of FIGS. 4A and 4B, it should be understood that other embodiments may include more, less, or different components. In this example, the inflatable support frame 110 includes a number of support members 405 and an inflation attachment point 410. As described in more detail below, the inflatable support frame 110 is configured to substantially inflate into a rigid or semi-rigid support frame to unfurl one or more thin-film PV panels 105 and maintain the thin-film PV panel(s) 105 at a desired orientation(s).

Each support member 405 here includes a preformed shape that includes an inner cavity surrounded by a pliable surface material, such as a rubber or plasticized material. For example, the surface material can be sealed at its edges to form the inner cavity. As another example, two or more surface materials can be connected to form the inner cavity. In certain embodiments, the inflatable support frame 110 can include a number of support members 405 coupled together at junction connectors 415. In certain embodiments, the junction connectors 415 provide additional seals to enclose the inner cavities of the support members 405. In other embodiments, the junction connectors 415 can include vias configured to allow compressed gas to pass between support members 405. In still other embodiments, the inflatable support frame 110 represents a single structure, such as a single rectangular structure 420 (“pillow”) as illustrated in FIG. 4B. The single structure can include a panel side adapted to couple to the thin-film PV panel 105 and a back side adapted to couple to one or more adjustable braces 125. In certain embodiments, at least one of the pliable support surfaces is the thin-film PV panel 105.

The inflation attachment point 410 is adapted to securely couple to the inflation hose 140. In certain embodiments, each support member 405 includes an inflation attachment point 410. In other embodiments, the inflatable support frame 110 includes a single inflation attachment point 410.

Compressed gas received from the canister 115 occupies and expands the cavity within each support member 405. As the cavity expands, the surface material unfolds and, as such, the support member 405 expands. In addition, as the support member 405 expands, the support member 405 unfurls the thin-film PV panel 105 coupled thereto. The support member 405 becomes increasingly rigid as a pressure of the gas within the cavity increases. Accordingly, at a certain pressure, the support member 405 achieves a sufficient rigidity to maintain an orientation of the thin-film panel 105.

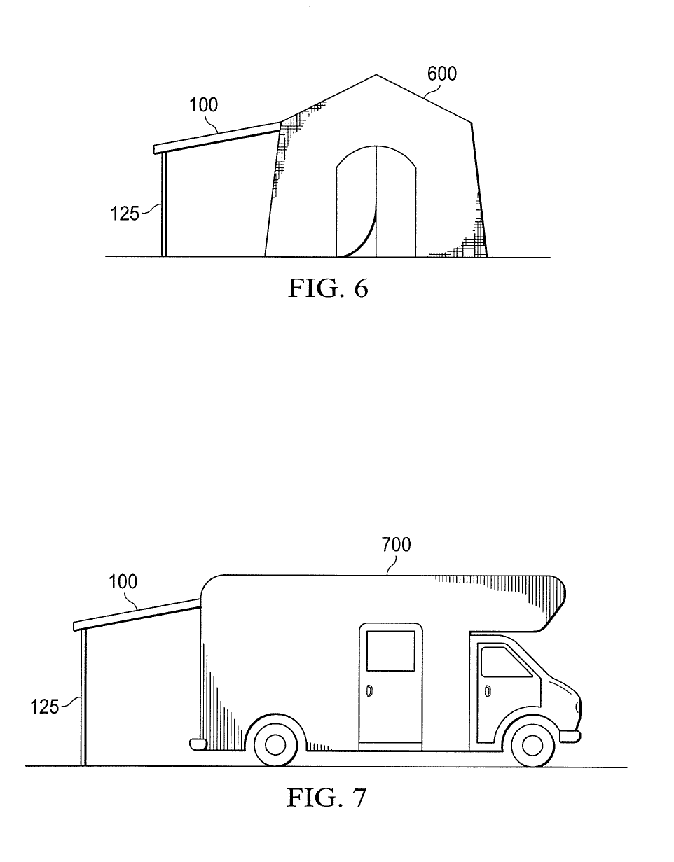

FIGS. 5 through 7 illustrate example electrical networks according to this disclosure. Although certain details will be provided with reference to the components of electrical networks in FIGS. 5 through 7, it should be understood that other embodiments may include more, less, or different components.

FIG. 5 illustrates an electrical network 500. In this example, the electrical network 500 includes a PV source 505, an electrical controller 510 and an electrical load 515. As described in more detail below, the electrical network 500 in this embodiment is configured to generate and provide electrical energy from a renewable source.

The PV source 505 provides electrical energy to the electrical network 500. For example, the PV source 505 can include one or more PV panel systems 100 or arrays 200 configured to receive solar energy and convert the solar energy to electrical energy, which is delivered to the electrical controller 510. The PV source 505 can deliver direct current (DC) electrical energy to the electrical controller 510. In certain embodiments, the electrical controller 510 includes a converter configured to convert the DC electrical energy into alternating current (AC) electrical energy. In this example, the electrical controller 510 includes a number of ports 520 adapted to couple to electrical devices. For example, at least one battery controller 525 may be coupled to the electrical controller 515 via at least one port 520 in order to provide a charge to one or more batteries 530. In certain embodiments, the electrical controller 520 includes a first set of ports 520 that can provide DC energy and a second set of ports 520 that can deliver AC energy.

In certain embodiments, the electrical network 500 is included as part of a larger structure. That is, the electrical network 500 could be part of a tent, boat, military vehicle, automobile, recreation vehicle (RV) or other vehicle or structure. In one example illustrated in FIG. 6, the PV panel system 500 could be included as a panel on a tent 600 in which inflation of the inflatable support frame 110 unfurls the thin-film PV panel 105 to expose the surface of the thin-film PV panel 105 to solar energy. In another example illustrated in FIG. 7, the PV panel system 500 could be included as a panel on an RV 700 in which inflation of the inflatable support frame 110 unfurls the thin-film PV panel 105 to expose the surface of the thin-film PV panel 105 to solar energy.

Modifications, additions, or omissions may be made to the systems, apparatuses, and methods described herein without departing from the scope of the invention. The components of the systems and apparatuses may be integrated or separated. Moreover, the operations of the systems and apparatuses may be performed by more, fewer, or other components. The methods may include more, fewer, or other steps. Additionally, steps may be performed in any suitable order. As used in this document, “each” refers to each member of a set or each member of a subset of a set.

To aid the Patent Office, and any readers of any patent issued on this application in interpreting the claims appended hereto, applicants wish to note that they do not intend any of the appended claims or claim elements to invoke paragraph 6 of 35 U.S.C. Section 112 as it exists on the date of filing hereof unless the words “means for” or “step for” are explicitly used in the particular claim.

What is claimed is:

1. A photovoltaic power system comprising:
a flexible panel (105) comprising a plurality of photovoltaic cells (305) configured to convert solar energy into electrical energy;
an inflatable support frame (110) coupled to the flexible support panel, the inflatable support frame configured to support to the flexible panel when inflated by a gaseous solution; and
an inflation connection point (140, 145) configured to receive the gaseous solution.

2. The photovoltaic power system of claim 1, wherein the inflatable support frame comprises an anchor member (130) configured to at least one of: maintain the flexible panel at a desired orientation and secure the photovoltaic power system in a desired position.

3. The photovoltaic power system of claim 1, wherein the inflatable support frame comprises an adjustable brace (125) configured to set the flexible panel at a desired orientation.

4. The photovoltaic power system of claim 1, further comprising a control canister (115) configured to store the gaseous solution and to provide the gaseous solution to the inflatable support frame.

5. The photovoltaic power system of claim 4, wherein the control canister comprises an inflation valve (135) configured to release the gaseous solution into the inflatable support frame in response to actuation.

6. The photovoltaic power system of claim 1, wherein the gaseous solution comprises one of: a compressed inert gas; a foam; human breath; engine exhaust; and vacuum cleaner discharge.

7. The photovoltaic power system of claim 1, further comprising:
an electrical connector (120) coupled to the photovoltaic cells, the electrical connector configured to couple the photovoltaic cells to at least one of: an electrical device and a second photovoltaic power system.

8. A method comprising:
erecting a support frame (110) by injecting a gaseous solution into a cavity of the support frame to inflate the support frame to a preformed shape;
unfurling a photovoltaic panel (105) coupled to the support frame; and
converting solar energy into electrical energy using the photovoltaic panel.

9. The method of claim 8, further comprising:
anchoring the support frame to at least one of: maintain the photovoltaic panel at a desired orientation and secure the support frame in a desired position.

10. The method of claim 8, wherein erecting the support frame comprises:
actuating a valve on a control canister (115) to inject the gaseous solution into the cavity.

11. The method of claim 8, wherein the gaseous solution comprises one of: a compressed inert gas; a foam; human breath; engine exhaust; and vacuum cleaner discharge.

12. The method of claim 8, wherein the photovoltaic panel comprises photovoltaic cells (305) having a resilient interconnection pattern configured to maintain a desired power output despite a loss of one or more photovoltaic cells.

13. The method of claim 8, further comprising:
coupling the photovoltaic panel to at least one of: an electrical device and a second photovoltaic panel.

14. An electrical system comprising:
a photovoltaic power system comprising:
a flexible panel (105) comprising a plurality of photovoltaic cells (305) configured to convert solar energy into electrical energy;
an inflatable support frame (110) coupled to the flexible support panel, the inflatable support frame configured to support to the flexible panel when inflated by a gaseous solution; and
an inflation connection point (140, 145) configured to receive the gaseous solution; and
an electrical controller (510) configured to couple an electrical load to the photovoltaic power system (505).

15. The electrical system of claim 14, wherein the inflatable support frame comprises an anchor member (130) configured to at least one of: maintain the flexible panel at a desired orientation and secure the photovoltaic power system in a desired position.

16. The electrical system of claim 14, wherein the inflatable support frame comprises an adjustable brace (125) configured to set the flexible panel at a desired orientation.

17. The electrical system of claim 14, a control canister (115) configured to store the gaseous solution and to provide the gaseous solution to the inflatable support frame.

18. The electrical system of claim 17, wherein the control canister comprises an inflation valve (135) configured to release the gaseous solution into the inflatable support frame in response to actuation and wherein the gaseous solution comprises one of: a compressed inert gas; a foam; human breath; engine exhaust; and vacuum cleaner discharge.

19. The electrical system of claim 14, wherein the photovoltaic cells comprise a resilient interconnection pattern configured to maintain a desired power output despite a loss of one or more photovoltaic cells.

20. The electrical system of claim 14, further comprising:
an electrical connector (120) coupled to the photovoltaic cells, the electrical connector configured to couple the photovoltaic cells to at least one of: the electrical load and a second photovoltaic power system.
